(19) United States
(12) Patent Application Publication
(10) Pub. No.: US 2007/0170547 A1
(43) Pub. Date: Jul. 26, 2007

(54) Semiconductor device and method for fabricating the same

(75) Inventors: Myung Il Chang, Gyeonggi-do (KR); Jin Hwan Lee, Gyeonggi-do (KR)

Correspondence Address: HELLER EHRMAN LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/448,685

(22) Filed: Jun. 8, 2006

(30) Foreign Application Priority Data
Jan. 26, 2006 (KR) 10-2006-0008294

(51) Int. Cl. H01L 29/00; H01L 21/00

(52) U.S. Cl. 257/532; 438/396; 438/926

(57) ABSTRACT

The semiconductor device includes a semiconductor substrate, a plate electrode, and a metal layer. The semiconductor substrate includes a capacitor region and a dummy region. The plate electrode is formed over the semiconductor substrate, wherein a dummy plug of the plate electrode is formed in the dummy region. The metal layer is formed over the plate electrode, the metal layer being in contact with the dummy plug.

### BACKGROUND OF THE INVENTION

The present invention relates to a memory device. More particularly, the present invention relates to a semiconductor device and a method for fabricating the same wherein a dummy plug is formed under a plate electrode that is connected with a metal layer, and a metal interconnect contact is formed in the dummy plug to increase the contact area of the metal interconnect contact without increasing the total thickness of the plate electrode, thereby improving interface resistance of the metal interconnect contact and increasing immunity for Vcp of the device.

FIG. 1 is a simplified cross-sectional view illustrating a semiconductor device.

Referring to FIG. 1, a first interlayer insulating film 40 is formed over a semiconductor substrate having a lower structure including a bit line 20, a storage node contact plug 25, and an etch barrier layer 30. The first interlayer insulating film 40 is etched using a storage node mask (not shown) as an etching mask to form a storage node region (not shown) exposing the lower structure. A lower electrode 55 is formed on the surface of the storage node region. A dielectric film (not shown) is formed over the lower electrode 55. A planarized plate electrode 80 fills up the storage node region to form a capacitor 85. A second interlayer insulating film 90 is formed over the plate electrode 80. A metal layer 95 is formed over the second interlayer insulating film 90, wherein the metal layer 95 includes a metal interconnect contact 97 connecting the plate electrode 80 with the metal layer 95.

According to the above method for fabricating a semiconductor device, the metal layer 95 is connected with the plate electrode 80. Vcp is applied to the plate electrode 80. Since the metal interconnect contact 97 connecting the metal layer 95 with the plate electrode 80 is simultaneously formed with a metal interconnect contact (not shown), connecting the metal layer 95 with a bit line in a peripheral circuit region, the metal interconnect contact 97 expands to the first interlayer insulating film 40 under the plate electrode 80. As a result, the interface resistance of the metal interconnect contact 97 is increased due to its reduced contact area.

In addition, if the interface resistance of the metal interconnect contact is increased, it is unable to apply Vcp to the plate electrode, or the voltage applied to the plate electrode is unstable due to external influence, thereby degrading sensing characteristics of BLSA (Bit line sense amplifier) during read/write operation of the device. As a result, the device may malfunction. When bias such as the auto-refresh in a test pattern may be varied, the test can fail because of the unstable Vcp.

However, if the thickness of the plate electrode is increased to increase contact area, the plate electrode used as a fuse of the device may not be cut in a fuse blowing process, or unwanted particles may be attached at sidewalls of a fuse box. As a result, the device may malfunction.

### BRIEF SUMMARY OF THE INVENTION

The present invention relates to a semiconductor device and a method for fabricating the same wherein a dummy plug is formed under a plate electrode that is connected to a metal layer, and a metal interconnect contact is formed to the dummy plug to increase contact area of the metal interconnect contact without increasing the total thickness of the plate electrode, thereby improving interface resistance between the plate electrode and the metal layer and thus increasing immunity for the Vcp of the device.

According to an embodiment of the present invention, a semiconductor device includes: a semiconductor substrate including a capacitor region and a dummy region; a plate electrode formed over the semiconductor substrate, wherein a dummy plug of the plate electrode is formed in the dummy region; and a metal layer formed over the plate electrode, the metal layer in contact with the dummy plug.

According to another embodiment of the present invention, a method for fabricating a semiconductor device includes: (a) forming a first interlayer insulating film over a semiconductor substrate including a capacitor region and a dummy region with a lower structure; (b) etching the first interlayer insulating film using a storage node contact mask as an etching mask to form a storage node region exposing the lower structure; (c) forming a lower electrode over the surface of the storage node region and forming a dummy contact hole exposing the lower structure in the dummy region; (d) filling the dummy contact hole and the storage node region with a plate electrode to form a capacitor in the capacitor region and a dummy plug in the dummy region; and (e) forming a metal layer in contact with the dummy plug over the plate electrode.

### BRIEF DESCRIPTION OF THE DRAWINGS

FIG. 1 is a simplified cross-sectional view illustrating a conventional semiconductor device;

FIG. 2 is a simplified cross-sectional view illustrating a semiconductor device according to one embodiment of the present invention; and

FIGS. 3a through 3g are simplified cross-sectional views illustrating a method for fabricating a semiconductor device according to one embodiment of the present invention.

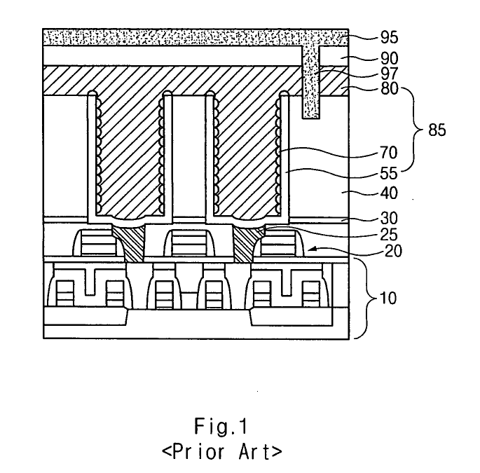

### DETAILED DESCRIPTION OF THE INVENTION

Reference will now be made in detail to exemplary embodiments of the present invention. Wherever possible, the same reference numbers will be used throughout the drawings to refer to the same or like parts. It should be appreciated that the embodiments are provided to describe and enable the invention to those skilled in the art. Accordingly, the embodiments described herein may be modified without departing from the scope of the present invention.

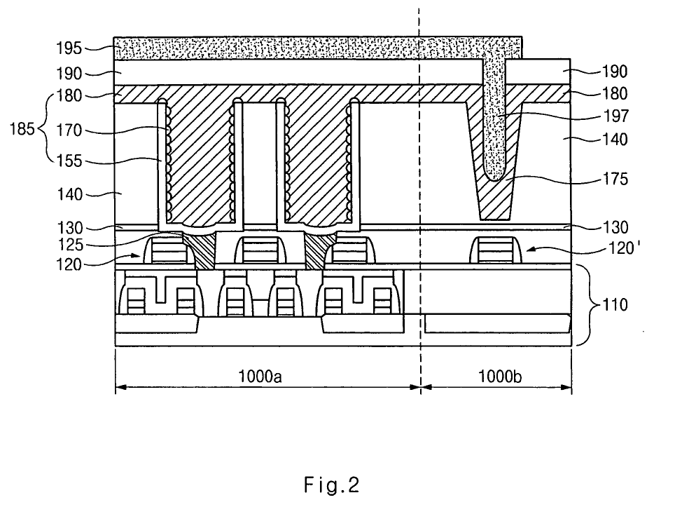

FIG. 2 is a simplified cross-section view illustrating a semiconductor device according to one embodiment of the present invention.

Referring to FIG. 2, a first interlayer insulating film 140 is formed over a semiconductor substrate 110 including a capacitor region 1000a and a dummy region 1000b with a lower structure including a bit line 120, a dummy bit line 120′, a storage node contact plug 125, and an etch barrier layer 130. A plate electrode 180 is formed over the first interlayer insulating film 140. In one embodiment of the present invention, in the capacitor region 1000a, a storage node region (not shown) is formed in the first interlayer insulating film 140. A capacitor 185 comprising a stacked structure of a lower electrode 155, a dielectric film (not shown), and the plate electrode 180 is formed in the capacitor region 1000a while a dummy plug 175 is formed in the first interlayer insulating film 140 in the dummy region 1000b. A metal layer 195 is formed over the plate electrode 180 in the capacitor region 1000a and the dummy region 1000b. In another embodiment, a metal interconnect contact 197 connecting the plate electrode 180 with the metal layer 195 is formed in the dummy plug 175. In addition, the dielectric film includes an ONO (Oxide-nitride-oxide) structure. A MPS (Metastable polysilicon) layer 170 may be further formed at the interface between the dielectric film and the lower electrode 155 so as to increase its contact area.

According to one embodiment of the present invention, forming the dummy plug 175 increases the contact area of the metal interconnect contact 197 to reduce contact resistance of the metal interconnect contact 197. The dummy region 1000b is disposed at the edge of a cell region. In another embodiment, the dummy plug 175 expands to the dummy bit line 120′ in the dummy region 1000b. Vcp is applied to the dummy bit line. As a result, there is a substantial process margin, which is capable of preventing malfunction of the device due to over-etching during the process for forming the metal interconnect contact 197.

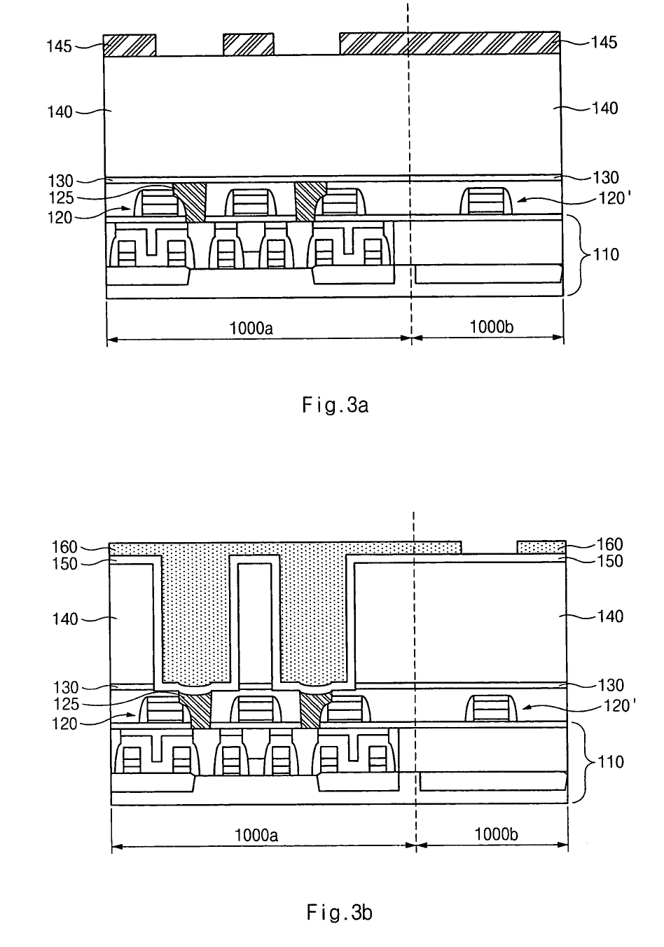

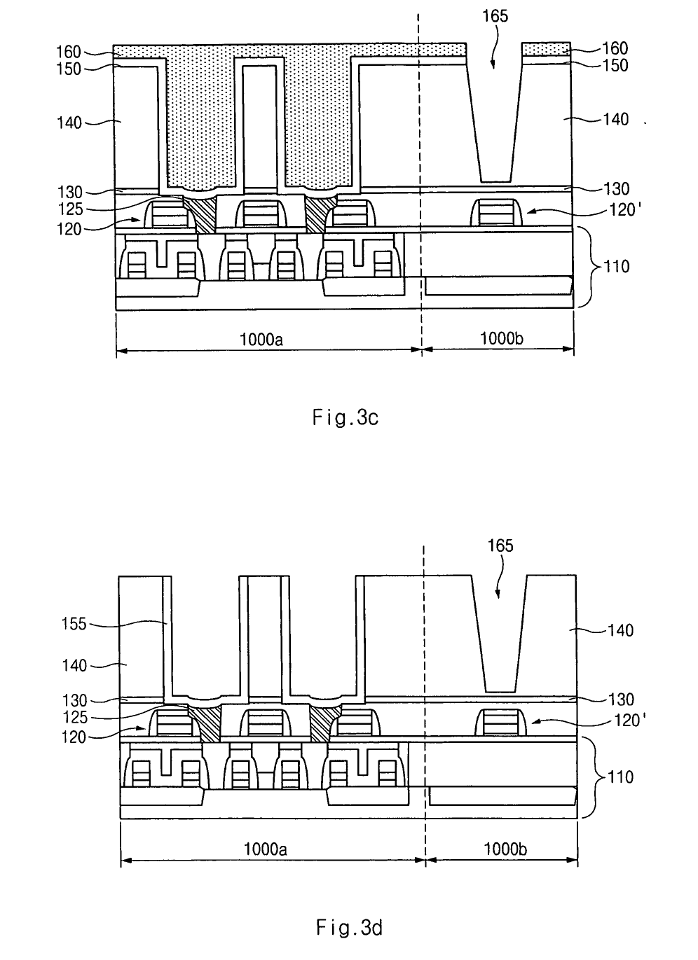

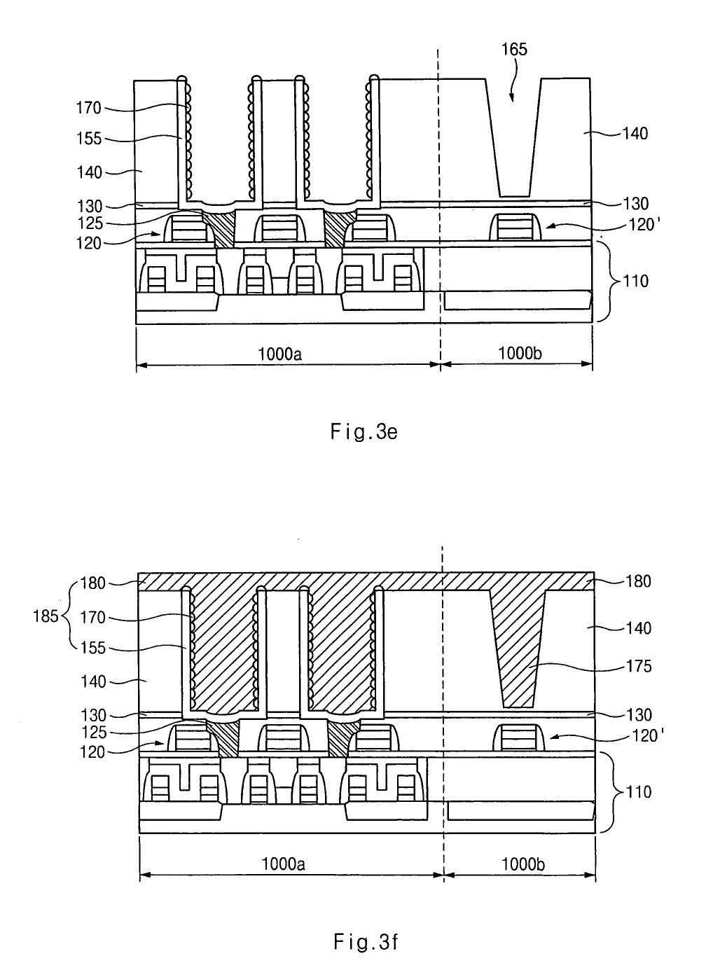

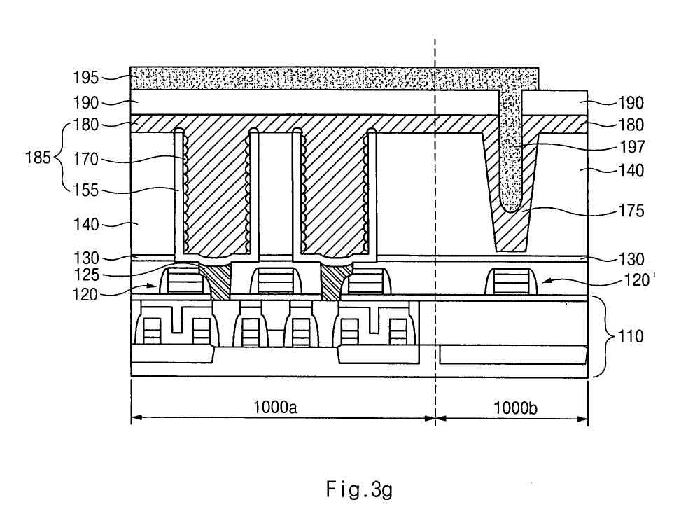

FIGS. 3a through 3g are simplified cross-sectional views illustrating a method for fabricating a semiconductor device according to an embodiment of the present invention.

Referring to FIG. 3a, a first interlayer insulating film 140 and a hard mask layer (not shown) are formed upon a lower structure such as a bit line 120, a dummy bit line 120′, a storage node contact plug 125, and an etch barrier layer 130 over a semiconductor substrate 110 including a capacitor region 1000a and a dummy region 1000b. The hard mask layer is etched using a storage node mask (not shown) as an etching mask to form a hard mask layer pattern 145 defining a storage node region (not shown).

Referring to FIG. 3b, the first interlayer insulating film 140 is etched using the hard mask layer pattern 145 as an etching mask to form the storage node region exposing the lower structure. After the hard mask layer pattern 145 is removed, a lower conductive layer 150 is formed over the entire surface of the resultant. A planarized photoresist film pattern 160 exposing a predetermined region of the dummy region 1000b is formed over the semiconductor substrate 110, wherein the photoresist film pattern 160 fills up the storage node region. In one embodiment of the present invention, the dummy region 1000b is disposed at the edge of a cell region. If a film having an irregular surface such as a MPS (Metastable polysilicon) layer and an ONO (Oxide-nitride-oxide) structure is formed on the semiconductor substrate 110 of the dummy region 1000b in a subsequent process, the expansion of the oxide film due to outside heat may make the subsequent metal interconnect contact deficient. Accordingly, the storage node region is not formed on the semiconductor substrate 110 of the dummy region 1000b, and formed only in the capacitor region 1000a. In addition, the removing process for the hard mask layer pattern 145 is performed using a CMP method or an etch-back method.

Referring to FIGS. 3c and 3d, the lower conductive layer 150 and the first interlayer insulating film 140 are etched using the photoresist film pattern 160 as an etching mask to form a dummy contact hole 165 exposing the etch barrier layer 130 in the dummy region 1000b. After the photoresist film pattern 160 is removed, the lower conductive layer 150 is planarized until the first interlayer insulating film 140 is exposed to form a lower electrode 155 for capacitor in the storage node region. In one embodiment, the planarizing process for the lower conductive layer 150 is performed using a CMP method or an etch-back method.

Referring to FIGS. 3e and 3f, a MPS layer 170 is formed over the lower electrode 155 in the storage node region so as to increase the surface area of the lower electrode 155. A dielectric film (not shown) is formed over the MPS layer 170. A plate electrode 180 is formed over the entire surface of the resultant to form a capacitor 185 in the capacitor region 1000a and a dummy plug 175 filling up the dummy contact hole 165 in the dummy region 1000b. In one embodiment, the capacitor 185 comprises a stacked structure of the lower electrode 155, the MPS layer 170, the dielectric film, and the plate electrode 180. In addition, the dielectric film comprises an ONO (Oxide-nitride-oxide) structure. Here, the dummy plug 175 can reduce the interface resistance of a subsequent metal interconnect contact. In another embodiment of the present invention, the dummy plug 175 expands to the dummy bit line 120′ in the dummy region 1000b. In addition, Vcp may be applied to the dummy bit line 120′. As a result, there is a substantial process margin, which is capable of preventing malfunction of the device due to an over-etching method during the subsequent process for forming the metal interconnect contact.

Referring to FIG. 3g, a second interlayer insulating film 190 is formed over the plate electrode 180. The second interlayer insulating film 190 and the dummy plug 175 in the dummy region 1000b are etched using a metal interconnect contact mask (not shown) to form a metal interconnect contact hole (not shown). A metal layer 195 filling up the metal interconnect contact hole is formed over the entire surface of the resultant to form a metal interconnect contact 197 connecting the plate electrode 180 with the metal layer 195. In one embodiment, the metal interconnect contact 197 is formed in the previously formed dummy plug 175 of the dummy region 1000b, thereby increasing the contact area of the metal interconnect contact 197, which results in reducing its contact resistance.

In addition, subsequent processes such as a process for forming a further interconnect, a process for forming a metal line, and a process for forming a fuse may be performed.

As described above, the semiconductor substrate and method for fabricating the same in accordance with an embodiment of the present invention provides forming a dummy plug under a plate electrode and forming a metal interconnect contact connecting the plate electrode with a metal layer in the dummy plug, thereby increasing the contact area of the metal interconnect contact without increasing the total thickness of the plate electrode. As a result, the contact resistance of the metal interconnect contact can be reduced. In addition, the total thickness of the plate electrode may maintain thin, which results in reducing the risk for laser cutting in the subsequent fuse repair process. Although the metal interconnect contact hole expands to the dummy bit line in the process for forming the metal interconnect contact, Vcp is applied to the dummy bit line, thereby improving drivability and immunity for Vcp of the device. As a result, there is a substantial process margin for the metal interconnect contact.

The foregoing description of various embodiments of the invention has been presented for purposes of illustration and description. It is not intended to be exhaustive or to limit the invention to the precise form disclosed, and modifications and variations are possible in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated.

What is claimed is:

1. A semiconductor device comprising:
a semiconductor substrate including a capacitor region and a dummy region;
a plate electrode formed over the semiconductor substrate, wherein a dummy plug of the plate electrode is formed in the dummy region; and
a metal layer formed over the plate electrode, the metal layer being in contact with the dummy plug.

2. The semiconductor device according to claim 1, wherein the dummy region is disposed at the edge of a cell region.

3. The semiconductor device according to claim 1, wherein the dummy plug expands to a dummy bit line at the bottom of the dummy region.

4. The semiconductor device according to claim 3, wherein Vcp is applied to the bit line.

5. The semiconductor device according to claim 1, further comprising a capacitor formed in the capacitor region.

6. A method for fabricating a semiconductor device comprising:
(a) forming a first interlayer insulating film over a semiconductor substrate including a capacitor region and a dummy region with a lower structure;
(b) etching the first interlayer insulating film using a storage node contact mask as an etching mask to form a storage node region exposing the lower structure;
(c) forming a lower electrode over the surface of the storage node region and forming a dummy contact hole exposing the lower structure in the dummy region;
(d) filling the dummy contact hole and the storage node region with a plate electrode to form a capacitor in the capacitor region and a dummy plug in the dummy region; and
(e) forming a metal layer in contact with the dummy plug over the plate electrode.

7. The method according to claim 6, wherein the dummy region is disposed at the edge of a cell region.

8. The method according to claim 6, wherein step (b) includes:
(b-1) forming a hard mask layer pattern over the first interlayer insulating film to define a storage node region;
(b-2) etching the first interlayer insulting film using the hard mask layer pattern as an etching mask to form the storage node region exposing the lower structure in the capacitor region; and
(b-3) removing the hard mask layer pattern.

9. The method according to claim 8, wherein the removing process for the hard mask layer pattern is performed using an etch-back method or a CMP method.

10. The method according to claim 6, wherein the storage node region is formed in the capacitor region.

11. The method according to claim 6, wherein step (c) includes:
(c-1) forming a lower conductive layer over the entire surface of the resultant;
(c-2) forming a photoresist film pattern exposing a predetermined region of the dummy region over the entire surface of the resultant, wherein the photoresist film pattern fills up the storage node region;
(c-3) etching the lower conductive layer and the first interlayer insulating film using the photoresist film pattern as an etching mask to form a dummy contact hole exposing the lower structure;
(c-4) removing the photoresist film pattern; and
(c-5) etching the lower conductive layer until the first interlayer insulating film is exposed to form a lower electrode for the capacitor at a sidewall of the storage node region.

12. The method according to claim 11, wherein the etching process for the lower conductive layer is performed using a CMP method or an etch-back method.

13. The method according to claim 6, wherein the capacitor comprises a stacked structure of the lower electrode, a dielectric film, and the plate electrode.

14. The method according to claim 13, wherein the dielectric film includes an ONO (Oxide-nitride-oxide) structure.

15. The method according to claim 13, further comprising forming a MPS (Metastable Polysilicon) layer at the interface between the lower electrode and the dielectric film.

16. The method according to claim 6, wherein the dummy plug expands to a dummy bit line at the bottom of the dummy region.

17. The method according to claim 16, wherein Vcp is applied to the dummy bit line.

18. The method according to claim 6, wherein step (e) includes:
(e-1) forming a second interlayer insulating film over the plate electrode;
(e-2) etching the second interlayer insulating film and the dummy plug using a metal interconnect contact mask to form a metal interconnect contact hole; and
(e-3) forming a metal layer filling up the metal interconnect contact hole over the second interlayer insulating film.
